(19) United States
(12) Patent Application Publication
(10) Pub. No.: US 2011/0292605 A1
(43) Pub. Date: Dec. 1, 2011

(54) HEAT-DISSIPATING HINGE AND A PORTABLE ELECTRONIC DEVICE WITH THE SAME

(76) Inventors: KUAN-CHIH CHEN, Shulin (TW); Chaio-Liang Tseng, Shulin (TW)

(21) Appl. No.: 12/791,833

(22) Filed: Jun. 1, 2010

(51) Int. Cl. H05K 7/20; E05F 1/12; E05D 5/10

(52) U.S. Cl. 361/695; 16/386; 16/303; 16/308; 361/704

(57) ABSTRACT

A portable electronic device has a cover, a base and a heat-dissipating hinge. The heat-dissipating hinge has a cam and a foot. The cam is attached to the cover. The foot abuts the cam and protrudes out of the base. When the cover is opened, the cam is rotated to push the foot protruding out of the base and standing on the table. Therefore the base is elevated to easily dissipate heat so heat dissipation efficiency of the portable electronic device is increased.

### BACKGROUND OF THE INVENTION

1. Field of the Invention

The present invention relates to a heat-dissipating hinge and a portable electronic device with the same, especially to a heat-dissipating hinge allowing a cover pivoting relative to a base.

2. Description of the Prior Arts

Notebook computers are widely used in modern life. As people need more from the notebook computers, the notebook computers need better electronic components to provide better functions. For example, the performances of CPUs, graphics cards and hard disks need to be increased. Increasing performance of electronic components raises heat generated during operation. Therefore, the notebook computers need to increase heat dissipation. However, the conventional ways to increase the heat dissipation are enlarging the inner space of the notebook computer, adding heat dissipation elements and so on. The conventional ways all enlarge the volume of notebook computer so that is not convenient for user to easily carry the notebook computer.

To overcome the shortcomings, the present invention provides a heat-dissipating hinge to mitigate or obviate the aforementioned problems.

### SUMMARY OF THE INVENTION

The main objective of the present invention is to provide a heat-dissipating hinge for a portable electronic device. A portable electronic device has a cover, a base and a heat-dissipating hinge. The heat-dissipating hinge has a cam and a foot. The cam is attached to the cover. The foot abuts the cam and protrudes out of the base. When the cover is opened, the cam is rotated to push the foot protruding out of the base and standing on the table. Therefore the base is elevated to easily dissipate heat so heat dissipation efficiency of the portable electronic device is increased.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a heat-dissipating hinge in accordance with the present invention;

FIG. 2 is another perspective view of the heat-dissipating hinge in FIG. 1;

FIG. 3 is an exploded perspective view of the heat-dissipating hinge in FIG. 1;

FIG. 4 is another exploded perspective view of the heat-dissipating hinge in FIG. 1;

FIG. 5 is a perspective view of a portable electronic device in accordance with the present invention with the heat-dissipating hinge in FIG. 1;

FIG. 6 is a partially enlarged view of the portable electronic device in FIG. 5;

FIG. 7 is an operational side view of the portable electronic device in FIG. 5, shown the cover opened;

FIG. 8 is an operational side view of the heat-dissipating hinge in FIG. 1, shown closed; and

FIG. 9 is an operational side view of the heat-dissipating hinge in FIG. 1, shown opened.

### DETAILED DESCRIPTION OF THE PREFERRED EMBODIMENTS

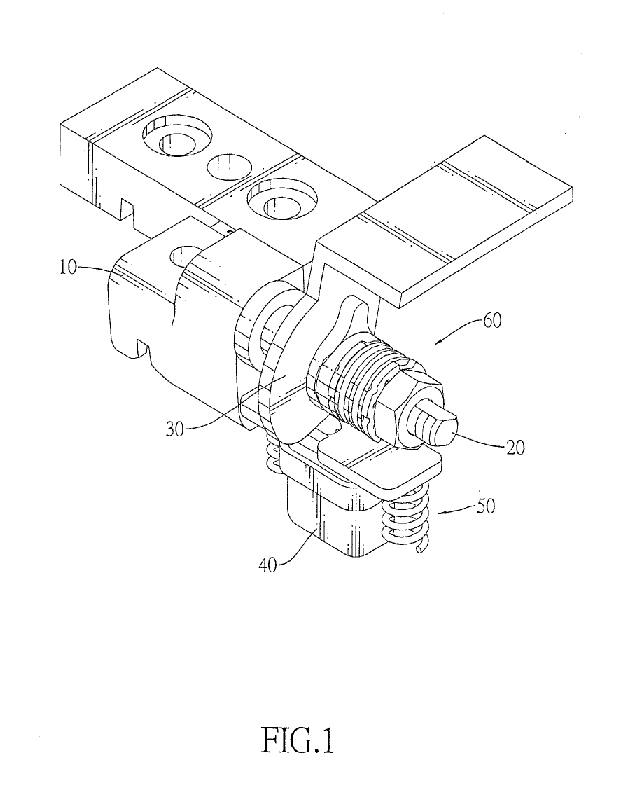

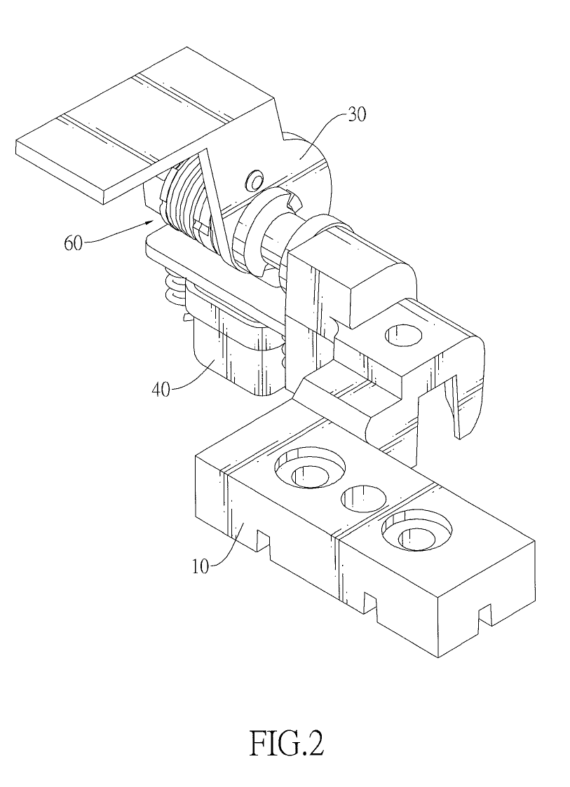

With reference to FIGS. 1 and 2, a heat-dissipating hinge 1 in accordance with the present invention comprises a stationary bracket 10, a pintle 20, a cam 30, a foot 40, a resilient element 50 and a torsion generating assembly 60.

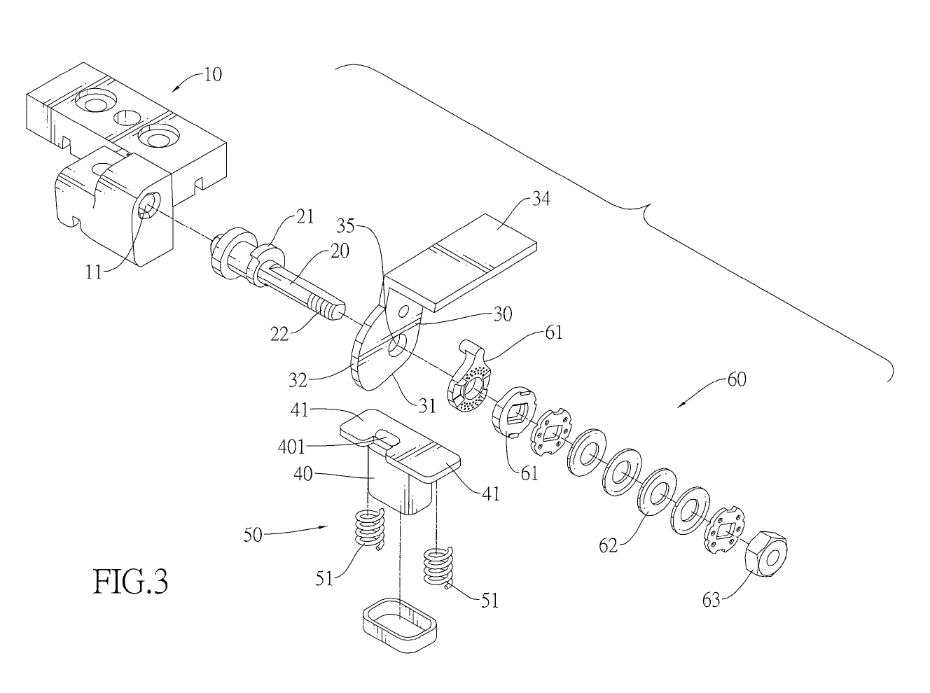

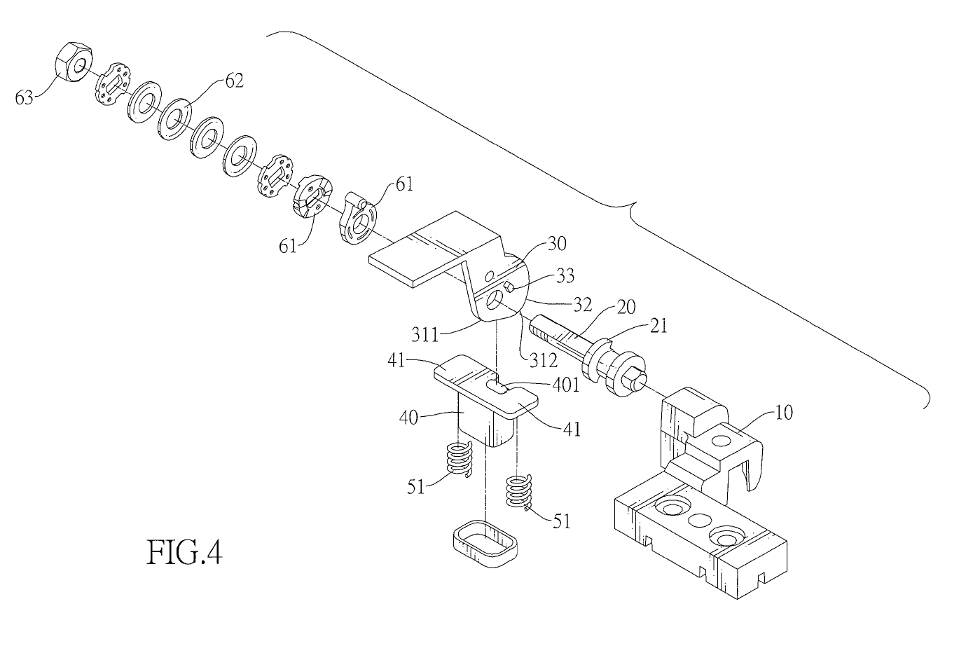

With reference to FIGS. 3 and 4, the stationary bracket 10 has a non-circular keyed hole 11.

The pintle 20 is connected securely to the stationary bracket 10 and may be engaged with the keyed hole 11 of the stationary bracket 10. The pintle 20 has a stop 21 and a threaded part 22. The stop 21 is formed on and protrudes transversely from an outside wall of the pintle 20. The threaded part 22 is formed around the outside wall of the pintle 20 near one end of the pintle 20.

The cam 30 is mounted rotatably around the pintle 20 via a pivoting hole 35 and has a lifting sector 31, a steady sector 32 and a limiting protrusion 33. The pivoting hole 35 has a center. The lifting sector 31 and the steady sector 32 are defined continuously on the cam 30. The lifting sector 31 has a radius that is a distance from the center of the pivoting hole 35 to a periphery edge of the lifting sector 31. The steady sector 32 has a radius that is a distance from the center of the pivoting hole 35 to a periphery edge of the steady sector 32. The radius of the lifting sector 31 is smaller than the radius of the steady sector 32. The periphery edge of the lifting sector 31 has a first end 311 and a second end 312. The second end 312 is connected to the periphery edge of the steady sector 32. The radius of the lifting sector 31 is gradually increased from the first end 311 to the second end 312. The radius of the steady sector 32 is constant. The limiting protrusion 33 is formed on a side of the cam 30 and selectively abuts the stop 21 of the pintle 20 to limit the rotating angle of the pintle 20.

The foot 40 selectively abuts the periphery edges of the lifting sector 31 and the steady sector 32 of the cam 30. In a preferred embodiment, the foot 40 has a tag 401 formed on a top surface thereof and selectively abutting the periphery edges of the lifting sector 31 and the steady sector 32 of the cam 30. The resilient element 50 abuts the foot 40 to push the foot 40 against the cam 30.

In a preferred embodiment, two extending wings 41 are formed respectively on two sides of the foot 40. The resilient element 50 comprises two springs 51 respectively abut the extending wings 41.

The torsion generating assembly 60 is mounted around the pintle 20 and comprises two positioning washers 61, multiple resilient discs 62 and a fastening washer 63. The positioning washers 61 have corresponding protrusions and detents to provide positioning function. The fastening washer 63 may be a nut to screw on to the threaded part 22 of the pintle 20. When the pintle 20 is rotated, the positioning washers 61 are pressed by the resilient discs 62 to rub against each other for providing torsion. The torsion generating assembly is well known in the art and may alternate as other means to provide torsion, such as resilient sleeve, abrasion washers. Aforesaid torsion generating assembly 60 is one of the preferred embodiments.

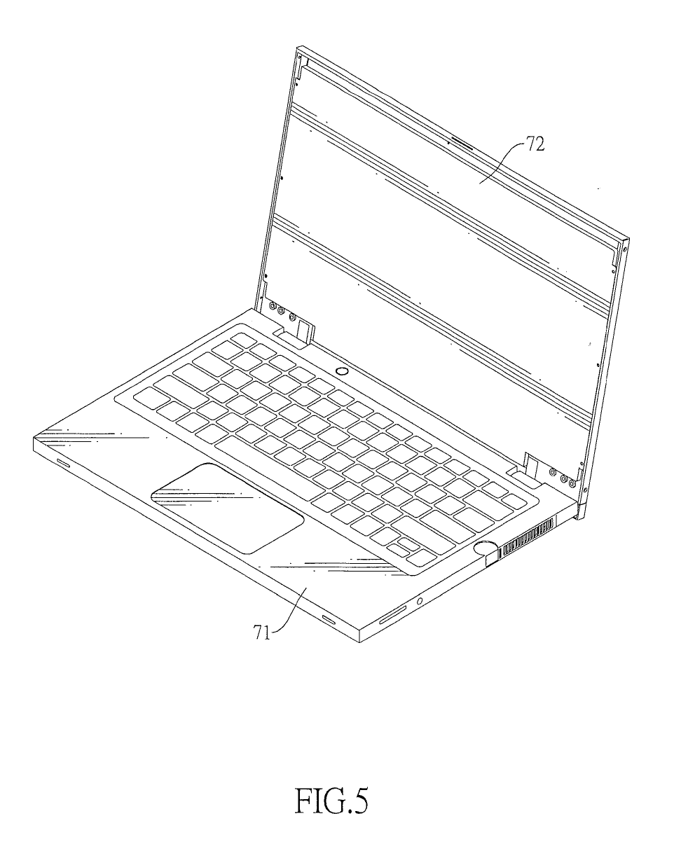

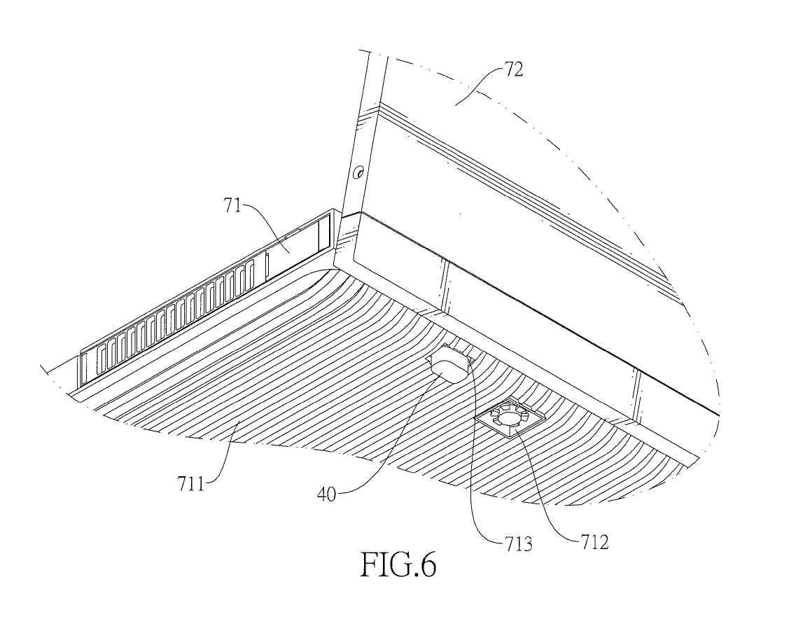

With reference to FIGS. 4 to 7, a portable electronic device 7 in accordance with the present invention comprises a base 71 and a cover 72 and two hinges 1 as described. The hinges 1 are mounted between the base 71 and the cover 72 to allow the cover 72 pivoted relative to the base 71. The stationary bracket 10 of each hinge 1 is attached to the base 71. The cam 30 of each hinge 1 is attached to the cover 72. In a preferred embodiment, the cam 30 has a connecting wing 34 protruding from a side of the cam 30 and attached to the cover 72. The base 71 has multiple elongated holes 711 formed through a bottom thereof for dissipate heat and a fan 712 mounted inside. The base 71 has two through holes 713 formed through the bottom thereof. The feet 40 of the hinges 1 respectively protrude through the through holes 713 of the base 71 and stand on the table 80. The springs 51 are pressed between the feet 40 and the base 71. The fan 712 is connected electrically to the circuit in the portable electronic device 7 or the hinges 1 so that the fan 712 is switched on when the cover 72 is opened.

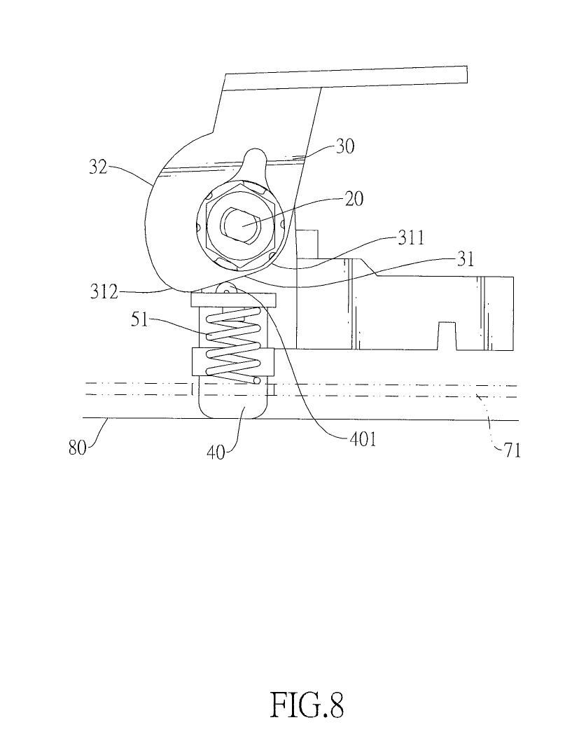

With reference to FIG. 8, when the portable electronic device 7 is not used, the cover is closed relative to the base 71. The elongated holes 711 are blocked by the table 80 and the tag 401 of the foot 40 abuts the periphery edge of the lifting sector 31 of the cam 30.

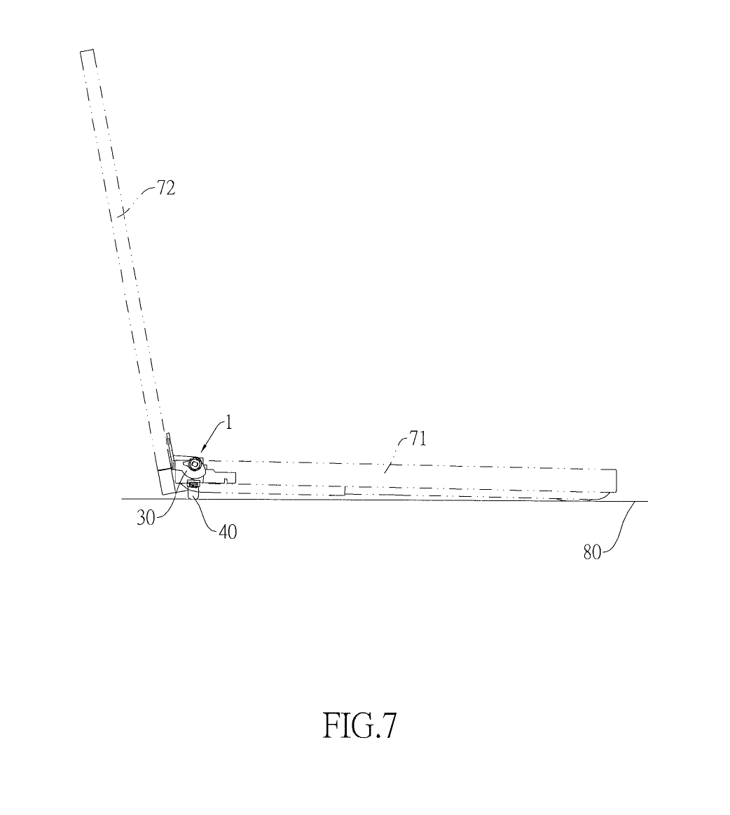

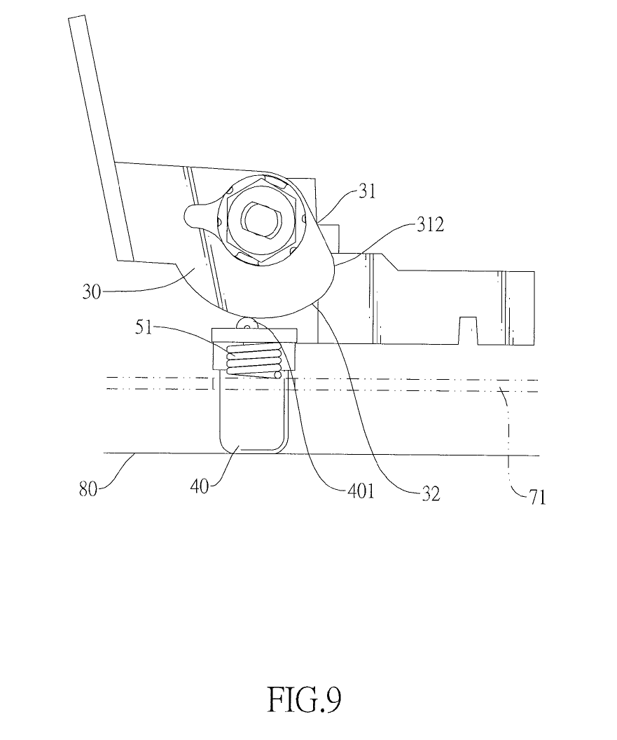

With reference to FIGS. 7 and 9, when the portable electronic device 7 is used, the cover 72 is opened so that the cam 30 is rotated simultaneously. As radius of the lifting sector 31 is increased, the foot 40 is pushed to protrude out of the base 71. Then the rear part of the base 71 is elevated so that the heat of the base 71 is easily dissipated out and the dissipation efficiency of the portable electronic device 7 is increased. Moreover, because the elongated holes 711 are also distant from the table 80, the elongated holes 711 have enough room to easily dissipate the heat. Furthermore, when the rear part of the base 71 is elevated, the base 71 is inclined for the user to easily use the keyboard on the base 71.

With reference to FIG. 9, the cover is opened to lead the periphery edge of the steady sector 32 abuts the tag 401 of the foot 40. Because the radius of the steady sector 32 is uniform, the base 71 stays at a certain height even the cover is opened to a larger angle. Therefore, the visual angle of the cover is adjustable without influence the stabilization of the base 71.

Moreover, the resilient element 50 is used to push the foot 40 to keep to abut against the cam 30 so that the cover does not shake while pivoting. However, the resilient element 50 may be omitted and the cam 30 is kept to lean on the foot 40 only by the weight of the base 71. Therefore, when one end of the foot 40 abuts against the table 80, the other end of the foot 40 continually abuts the cam 30 to stable the pivot of the cover. The resilient element 50 and the torsion generating assembly 60 are well known in the art and may be altered as other embodiment.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A heat-dissipating hinge comprising:
a stationary bracket;
a pintle connected securely to the stationary bracket;
a cam mounted rotatably around the pintle and having a lifting sector and a steady sector defined continuously on the cam, wherein a radius of the lifting sector is smaller than a radius of the steady sector; and
a foot selectively abutting periphery edges of the lifting and steady sectors of the cam.

2. The heat-dissipating hinge as claimed in claim 1, wherein
the radius of the steady sector of the cam is uniform; and
the periphery edge of the lifting sector has a first end and a second end, the second end is connected to the periphery edge of the steady sector and the radius of the lifting sector is gradually increased from the first end to the second end.

3. The heat-dissipating hinge as claimed in claim 1, wherein the foot has a tag formed on a top surface of the foot and selectively abutting the periphery edges of the lifting and steady sectors of the cam.

4. The heat-dissipating hinge as claimed in claim 2, wherein the foot has a tag formed on a top surface of the foot and selectively abutting the periphery edges of the lifting and steady sectors of the cam.

5. The heat-dissipating hinge as claimed in claim 1 further comprising a resilient element having two springs, wherein
the foot has two extending wings formed respectively on two sides of the foot; and
the springs respectively abut the extending wings.

6. The heat-dissipating hinge as claimed in claim 1 further comprising a torsion generating assembly mounted around the pintle.

7. The heat-dissipating hinge as claimed in claim 6, wherein the torsion generating assembly comprises
two positioning washers mounted around the pintle and having corresponding protrusions and detents; and
at least one resilient disc mounted around the pintle and abutting one of the positioning washers.

8. A portable electronic device with at least one heat-dissipating hinge as claimed in claim 1 comprising
a base having a through hole formed through a bottom of the base;
a cover connected pivotally to the base;
the at least one heat-dissipating hinge mounted between the base and the cover;
the stationary bracket of each one of the at least one heat-dissipating hinge attached to the base;
the cam of each one of the at least one heat-dissipating hinge attached to the cover; and
the foot of each one of the at least one heat-dissipating hinge protrudes through the through hole of the base.

9. The portable electronic device as claimed in claim 8 further comprising a fan, wherein
the base has multiple elongated holes; and
the fan is mounted in the base.

10. A portable electronic device with at least one heat-dissipating hinge as claimed in claim 5 comprising
a base having a through hole formed through a bottom of the base;
a cover connected pivotally to the base;
the at least one heat-dissipating hinge mounted between the base and the cover;
the stationary bracket of each one of the at least one heat-dissipating hinge attached to the base;
the cam of each one of the at least one heat-dissipating hinge attached to the cover;
the foot of each one of the at least one heat-dissipating hinge protrudes through the through hole of the base; and
the resilient element of each one of the at least one heat-dissipating hinge pressed between the foot and the base.

11. The portable electronic device as claimed in claim 10 further comprising a fan, wherein
the base has multiple elongated holes; and
the fan is mounted in the base.
